(19) United States
(12) Patent Application Publication
(10) Pub. No.: US 2026/0096236 A1
(43) Pub. Date: Apr. 2, 2026

(54) ELECTRONIC DEVICES WITH BEHIND-DISPLAY SENSING

(71) Applicant: Apple Inc., Cupertino, CA (US)

(72) Inventors: Patrick Llull, Los Altos, CA (US); Jean-Pierre S. Guillou, La Jolla, CA (US); Patrick A. Carroll, Santa Cruz, CA (US); Paul C. Kelley, San Francisco, CA (US)

(21) Appl. No.: 19/324,007

(22) Filed: Sep. 9, 2025

Related U.S. Application Data
(60) Provisional application No. 63/700,492, filed on Sep. 27, 2024.

(51) Int. Cl. H10F 39/00; G02B 5/30; G02B 13/00; H10H 29/30; H10H 29/855; H10K 59/35; H10K 59/65; H10K 59/80

(52) U.S. Cl. CPC H10F 39/806; G02B 5/3083; G02B 13/0075; H10H 29/352; H10H 29/855; H10K 59/353; H10K 59/65; H10K 59/878; H10H 29/8552; H10K 59/8792

(57) ABSTRACT

Embodiments are directed to electronic devices that include a behind-display imaging device and at least one birefringent layer positioned between the behind-display imaging device and a cover layer of the electronic device. In some instances, the birefringent layer(s) may be configured to obscure the presence of light-transmitting regions of the display in an imaging region of the display. Additionally or alternatively, the birefringent layer(s) may help to reduce image artifacts in images captured by the imaging device.

### CROSS-REFERENCE TO RELATED APPLICATIONS

This application claims the benefit under 35 U.S.C. § 119 (e) of U.S. Provisional Patent Application No. 63/700,492, filed Sep. 27, 2024, the disclosure of which is hereby incorporated herein by reference in its entirety.

### FIELD

This disclosure relates generally to electronic devices with a behind-display imaging device. More particularly, the disclosure relates to electronic device that include one or more birefringent layers positioned between the image device and a cover layer of the electronic device.

### BACKGROUND

Many electronic displays include a display and an imaging device, such as a camera or an ambient light sensor. When an electronic device incorporates a display and an imaging device into a common side of electronic device, the imaging device and display are conventionally placed in a side-by-side manner. This may limit the size of the display for a given footprint of the electronic device, as a bezel region of the electronic device may need to be sized in order to accommodate the imaging device. Accordingly, in some instances it may be desirable to configuration an imaging device behind a display, such that the imaging device collects light through a portion of the display. These behind-display imaging devices require local changes to a display (e.g., to allow light to pass through an imaging region of the display) that may be visible to a user. Additionally, images captured by a behind-display imaging device may suffer from image artifacts, such as caused by the diffraction of light as it passes through the display. Accordingly, it may be desirable to provide improved electronic devices with behind-display imagine devices.

### SUMMARY

Embodiments described herein are direct to electronic device that include a set of birefringent layers positioned between a display and a cover layer. Some embodiments are directed to an electronic device that includes a cover layer, a display, an imaging device positioned to collect light through an imaging region of the display, and a layer stack positioned between the imaging device and the cover layer. The layer stack includes a set of birefringent layers, a retarder layer, and a polarizing layer. The set of birefringent layers is configured to split incoming rays of light into ordinary rays and extraordinary rays, the retarder layer is configured to reduce a phase difference between the ordinary rays and the extraordinary rays, and the polarizing layer is configured to convert the ordinary rays and the extraordinary rays into a common polarization state.

In some variations, the polarizing layer is a 45-degree polarizer. In other variations, the polarizing layer is a depolarizer. The set of birefringent layers may include a plurality of birefringent layers. Additionally or alternatively, the retarder layer may be configured as a continuous layer. Additionally or alternatively, the polarizing layer may be configured as a continuous layer.

Other embodiments are directed to an electronic device that includes a cover layer, a display, and a plurality of stacked birefringent layers positioned between the display and the cover layer. The plurality of stacked birefringent layer is configured to split incoming rays of light into ordinary rays and extraordinary rays having an overall angle-dependent ray displacement. The plurality of stacked birefringent layer includes a first birefringent layer having a first optical axis, and a second birefringent layer having a second optical axis with a different orientation that the first optical axis.

In some variations, the first birefringent layer is configured to provide a first angle-dependent ray displacement in a first direction, and the second birefringent layer is configured to provide a second angle-dependent ray displacement in the first direction. Additionally or alternatively, the electronic device may include an imaging device, such that the plurality of stacked birefringent layers is positioned between the imaging device and the cover layer. In some of these variations, the imaging device is positioned to collect light through an imaging region of the display. The display may include a peripheral region at least partially surrounding the imaging region. In some of these variations, the display has a higher pixel density in the peripheral region than in the imaging region. In some variations, the plurality of stacked birefringent layers is positioned between the display and the cover layer within the imaging region, and the plurality of stacked birefringent layers is not positioned between the display and the cover layer within the peripheral region. In some of these variations, an additional optical material is positioned between the display and the cover layer within the peripheral region, wherein the additional optical material is coplanar with the plurality of stacked birefringent layers.

Still other embodiments are directed to an electronic device that includes a cover layer, a display comprising an imaging region and a peripheral region at least partially surrounding the imaging region, an imaging device positioned to collect light through an imaging region, and a set of birefringent layers. The set of birefringent layers is positioned between the display and the cover layer within the imaging region, and the set of birefringent layers is not positioned between the display and the cover layer within the peripheral region. In some of these variations, the display has a higher pixel density in the peripheral region than in the imaging region. Additionally or alternatively, the electronic device includes an additional optical material positioned between the display and the cover layer within the peripheral region, wherein the additional optical material is coplanar with the set of birefringent layers. In some variations, the additional optical material is an optically clear adhesive. In other variations, the additional optical material and the cover layer are formed from a common material. The display may include a display stack and an opaque backing layer positioned behind the display stack. The opaque backing layer may define an aperture that is positioned over the imaging device.

In addition to the example aspects and embodiments described above, further aspects and embodiments will become apparent by reference to the drawings and by study of the following description.

### BRIEF DESCRIPTION OF THE DRAWINGS

The disclosure will be readily understood by the following detailed description in conjunction with the accompanying drawings, wherein like reference numerals designate like structural elements, and in which:

FIG. 1A depicts a perspective view of an electronic device having a display, wherein the display includes an imaging region through which a behind-display imaging device may capture an image. FIG. 1B depicts a front view of an arrangement of pixels of the display of FIG. 1A. FIG. 1C depicts a partial cross-sectional side view of the electronic device 100 of FIG. 1A.

FIGS. 2A-2C depict partial cross-sectional side views of a variation of an electronic device that includes a birefringent layer positioned between a behind-display imaging device and a cover layer of the electronic device.

FIG. 3 depicts a partial cross-sectional side views of a variation of an electronic device as described herein, wherein the electronic device includes a plurality of birefringent layers positioned between a behind-display imaging device and a cover layer of the electronic device.

FIGS. 4A and 4B depict partial cross-sectional side views of a variation of an electronic device, wherein the electronic device includes one or more birefringent layers, a phase retarder, and a polarizer, between a behind-display imaging device and a cover layer of the electronic device.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures. Indeed, certain elements are depicted in cross-sectional views herein without cross-hatching facilitate illustration and description of the principles of the present disclosure.

It should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

In electronic devices that include a display, the display typically includes a display stack having various opaque elements (e.g., light-emitting elements, drive circuits, conductive traces) that can reflect, absorb, diffuse, and diffract light entering. In many instances, the density of these opaque elements may make the display stack, as a whole, seem relatively opaque. In instances where it is desirable to capture images through the display stack of a display (e.g., using a behind-display imaging device), it may be desirable to design a display (or a particular region thereof) to increase the amount of light that is transmitted through the display. Depending on the design of the display, light may interact with these opaque elements in a manner that causes light to diffract as it passes through the display, which may result in diffraction-based artifacts in images captured by a behind-display imaging device.

The following disclosure relates to electronic devices that include a behind-display imaging device and at least one birefringent layer positioned between the behind-display imaging device and a cover layer of the electronic device. In some instances, the birefringent layer(s) may be configured to obscure the presence of light-transmitting regions of the display in an imaging region of the display. Additionally or alternatively, the birefringent layer(s) may help to reduce image artifacts in images captured by the imaging device.

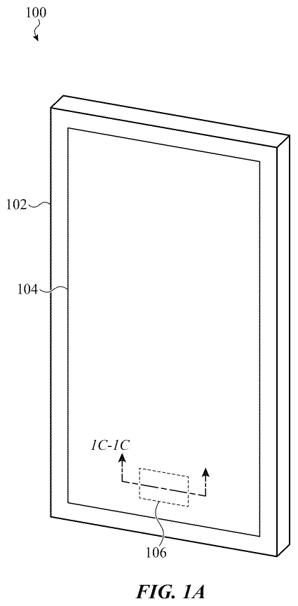

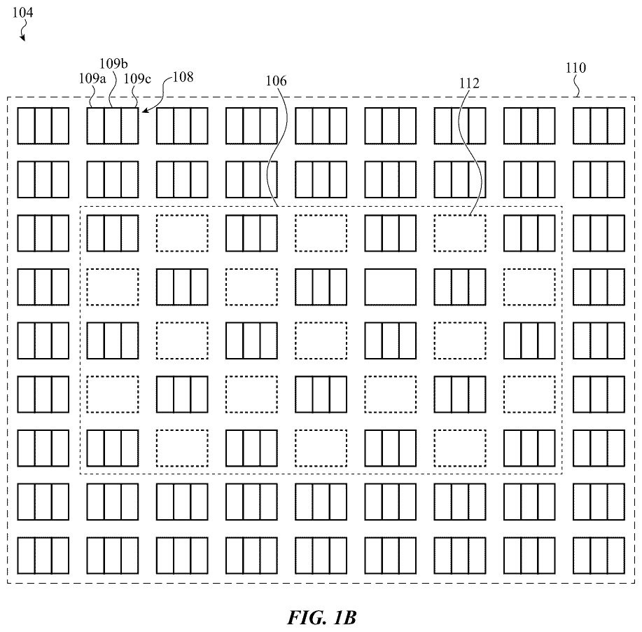

These and other embodiments are discussed below with reference to FIGS. 1A-4B. However, those skilled in the art will readily appreciate that the detailed description given herein with respect to these figures is for explanatory purposes only and should not be construed as limiting.

FIG. 1A shows a perspective view of example of an electronic device 100 as described herein. The electronic device 100 includes a housing 102 and a display 104, where the housing 102 at least partially surrounds or supports the display 104. The display 104 may include an imaging region 106 through which the electronic device 100 may capture images via a behind-display imaging device (not shown in FIG. 1A). The display 104 includes an array of display pixels, where each display pixel may be operated to generate light during operation of the display 104. While the imaging region 106 is depicted in FIG. 1A as having a rectangular shape, it should be appreciated that the imaging region 106 may have any suitable shape (e.g., a circular shape, an oval shape, an irregular shape, or the like).

To facilitate imaging through the imaging region 106, the display 104 may be configured to include a plurality of light-transmitting regions, each of which represents a portion of the display 104 that is at least partially transparent such that light may pass through display 104 via the light-transmitting region. Because the display pixels of the display 104 and their associated circuitry (e.g., electrical traces, circuit components such as thin-film transistors) may block light from passing through the display, the display 104 may have a locally reduced pixel density in the imaging region 106. This may allow for the display 104 to have larger light-transmitting regions within the imaging region 106 while maintaining a higher pixel density in other regions of the display 104 (which improve the quality of visual content displayed on the display 104).

For example, FIG. 1B shows a front view of a portion of the display 104 of FIG. 1A that depicts an example arrangement of display pixels 108. While only a single display pixel 108 is labeled in FIG. 1B for simplicity of illustration, it should be appreciated that additional similarly configured elements in FIG. 1B represent other display pixels of the display 104. Each display pixel 108 may, depending on the design of the display 104, include a single pixel or an array of subpixels. For example, in the variation, the display pixels 108 each include a plurality of subpixels 109a-109c, each of which is operable to emit a different color. Accordingly, by operating the individual subpixels 109a-109c individually or together, the display pixel 108 may be operable to emit a wide range of colors. While the display pixels 108 are each shown in FIG. 1B as including three subpixels (e.g., a first subpixel 109a, a second subpixel 109b, and a third subpixel 109c, which in some instances may be configured to generate red, green and blue light, respectively), it should be appreciated that a display pixel 108 may be designed to have a different number of subpixels (e.g., two or four or more subpixels).

The display 104 includes a peripheral region 110 that at least partially surrounds the imaging region 106. In some instances, such as shown in FIG. 1B, the peripheral region 110 may entirely surround the imaging region 106. In other instances, the imaging region 106 may be positioned at an edge of the display 104 such that a side of the imaging region 106 coincides with a corresponding edge of the display 104. In these instances, the peripheral region 110 may partially surround the imaging region 106 (e.g., may surround the remaining sides of the imaging region 106). The display 104 is configured such that the display pixels 108 are distributed within the peripheral region 110 according to a first pixel density. In these instances, the display pixels 108 may be distributed according to rectangular grid pattern having rows and columns in which immediately adjacent display pixels 108 are separated by a first set of inter-pixel distances. The inter-pixel distance between two adjacent display pixels 108 is referred to herein as the “pitch.” Within the peripheral region 110, the display pixels 108 positioned along a given row may be separated by a corresponding first average row pitch and the display pixels 108 positioned along a given column may be separated by a corresponding first average column pitch. In some of these variations, the row pitch and the column pitch are the same within the peripheral region 110.

Conversely, the display pixels 108 positioned within the imaging region 106 are distributed with a second pixel density that is less than the first pixel density. Specifically, the average pitch of the display pixels within the imaging region 106 may be less than a corresponding average pitch of the display pixels within the peripheral region 110. For example, the display pixels 108 within the imaging region 106 may be arranged in a grid pattern having rows and columns, but the display pixels 108 may be separated on average by a larger pitch along the rows (e.g., a second average row pitch that is larger than the first average row pitch) and columns (e.g., a second average column pitch that is larger than the first average column pitch). In effect, the display pixels 108 in the imaging region 106 may be distributed according to the same grid pattern as the display pixels 108 in the peripheral region 110, with certain display pixels 108 omitted in the imaging region 106. While the display pixels 108 are shown in FIG. 1B as having the same size in the imaging region 106 and the peripheral region 110, it should be appreciated that the display pixels 108 within the imaging region 106 may have a different size than the display pixels 108 within the peripheral region 110. For example, in some variations the display 104 may be configured such that the peripheral region 110 includes a first array of display pixels 108 having a first pixel density and a first pixel size and the imaging region 106 includes a second array of display pixels 108 having a second pixel density (less than that first pixel density) and a second pixel size (larger than the first pixel size).

Decreasing the pixel density within the imaging region 106 may increase the spacing between certain display pixels 108 within the imaging region 106, and may thereby define a set of light-transmitting regions 112 of the display 104. While only a single light-transmitting region 112 is labeled in FIG. 1B for simplicity of illustration, it should be appreciated that additional similarly configured elements in FIG. 1B represent other light-transmitting regions 112 of the display 104. Each light-transmitting region 112 represents a corresponding portion of the display 104 through which light may pass. Accordingly, the light-transmitting regions 112 correspond to regions of the display 104 that are free of display components that prevent light from traveling through the display 104. While the light-transmitting regions 112 depicted in FIG. 1B as being rectangular in shape, it should be appreciated that the light-transmitting regions 112 may have any suitable shape depending on the design of the display 104. By increasing the pitch between certain display pixels 108 within the imaging region 106 (e.g., as compared to pitch in the peripheral region 110), the display 104 may facilitate collection of sufficient light through the display 104 to perform one or more imaging operations.

For example, the electronic device 100 may include a behind-display imaging device 120. Specifically, FIG. 1C shows a partial cross-sectional side view of the electronic device 100 of FIG. 1A, taken along line 1C-IC, in which the imaging device 120 is be positioned behind the imaging region 106 of the display 104. Accordingly, the imaging device 120 may collect light that passes through the display 104 (e.g., via the light-transmitting regions 112). As shown in FIG. 1C, the display 104 may include a display stack 114 that includes the various functional layers of the display stack (such as, but not limited to, thin-film transistor layers, capacitive touch sensing layers, light emitting layers, encapsulation layers, support substrates, or the like) and defines the display pixels 108 of the display 104. The components of the display stack may depend at least in part on the type of display (e.g., a light-emitting diode display such as an organic light-emitting diode (OLED) display or a quantum dot light-emitting diode (QLED) display, an electroluminescent display, or the like).

The electronic device may include a cover layer 116. The cover layer 116 may define an exterior surface of the electronic device 100, and may act to protect the various components of the display stack 114. The cover layer 116 may be formed from one or more transparent materials, such as glass, crystal (e.g., sapphire), a transparent polymer (e.g., plastic), or the like, which allows a user to view the display 104 through the cover layer 116. In some instances, the cover layer 116 may act as an input surface, such that the electronic device 100 is configured to detect contact between the user and the cover layer 116 (e.g., using a capacitive touch sensor or the like).

In some variations, the display 104 may include an opaque backing layer 118 that is positioned behind a portion of the display stack 114. The opaque backing layer 118 may be configured to reflect and/or absorb light that is incident on the opaque backing layer 118, and may thereby act to prevent light from passing through certain portions of the display 104. For example, in the variation shown of the electronic device 100 shown in FIGS. 1A-1C, the opaque backing layer 118 may be positioned behind the display stack 114 within the peripheral region 110 of the display 104, such that light that is incident on the peripheral region 110 (e.g., received through the cover layer 116) and that passes through the display stack 114 will be absorbed and/or reflected by the opaque backing layer 118. Accordingly, the peripheral region 110 of the display 104 may be effectively opaque, such that little or no light passes through the display 104 in the peripheral region 110.

Conversely, the opaque backing layer 118 may not be positioned in the imaging region 106 of the display 104. For example, the opaque backing layer 118 may define an aperture 119 extending through the opaque backing layer 118, such that light may passes through the display 104 via the aperture 119. Accordingly, in variations where the display 104 include an opaque backing layer 118, an aperture 119 defined to extend through the opaque backing layer 118 may at least partially define the imaging region 106 of the display 104. Accordingly, the aperture may be positioned over the imaging device 120, such that the imaging device 120 collects light through the aperture 119.

The imaging device 120 may include one or more sensors that are configured to measure incoming light that passes through the imaging region 106 of the display 104. For example, the imaging device 120 is shown in FIG. 1C as including a sensor 122. The sensor 122 may include a single photosensitive element, or may include an array of photosensitive elements. For example, in some variations the sensor 122 may be configured as an image sensor that includes an array of imaging pixels. Each imaging pixel may include a photodiode that is configured to absorb photons a generate a corresponding charging via the photoelectric effect, and the imaging pixel may be configured to store these charges as part of an imaging operation. The image sensor may be configured with circuitry to control the operation and readout of the array of imaging pixels in order to generate an image. For example, the image sensor may include row and column circuits that are used to selectively access and readout each image sensor pixel, and may include analog processing circuitry that is configured to read out the charge collected by the imaging pixels and convert the analog measurements to a digital signal. It should be appreciated that the imaging device 120 may include any suitable sensor or sensors as may be desired, such as a CCD (charge-coupled device) sensor, a CMOS (complementary metal oxide semiconductor) sensor, a SPAD (single photon avalanche diode) sensor, combinations thereof, or the like.

The imaging device 120 may include one or more optical components positioned between the sensor 122 and the display 104. These optical components may include one or more lenses, filters, irises, or the like, which may be used to shape or otherwise modify light after it has passed through the display 104. For example, the imaging device 120 is shown in FIG. 1C as including a lens 124 positioned between the sensor 122 and the display 104 that is configured to receive incoming light (represented by arrows 126) that has passed through the display 104 and to focus the light onto the sensor 122. Additionally, the imaging device 120 may include one or more support structures that are configured to position the various components of the imaging device 120 relative to the display 104. For example, the variation of the imaging device 120 shown in FIG. 1C includes a support structure 128 that is configured to support the sensor 122 and to mount the sensor 122 relative to the display stack. It should be appreciated that FIG. 1C illustrates one illustrative example arrangement of the imaging device 120, and it should be appreciated that the various concepts described herein may apply to electronic devices having a wide range of possible imaging devices.

Depending on the design of the display of an electronic device, the difference in pixel density between the imaging region of a display (e.g., the imaging region 106 of the display 104 of FIGS. 1A-1C) and the surrounding regions of the display (e.g., the peripheral region 110 of the display 104) may be visible to a user. For example, when the display is generating visual content, the light-transmitting regions of the display that are positioned within the imaging region may appear to a user as darkened areas of the display, which may draw a user's attention to the location of the imaging region. Accordingly, it may be desirable to mitigate the impact of the reduced pixel density in the imaging region of a display.

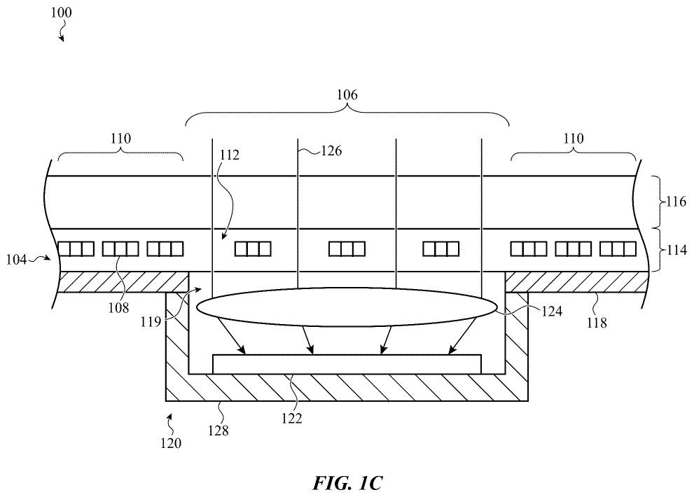

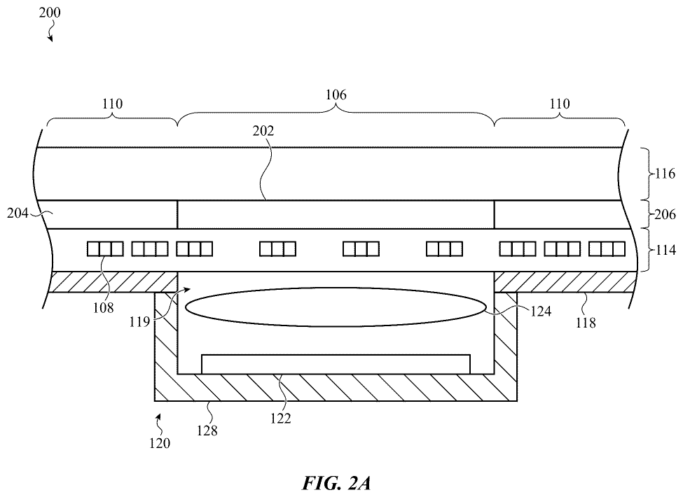

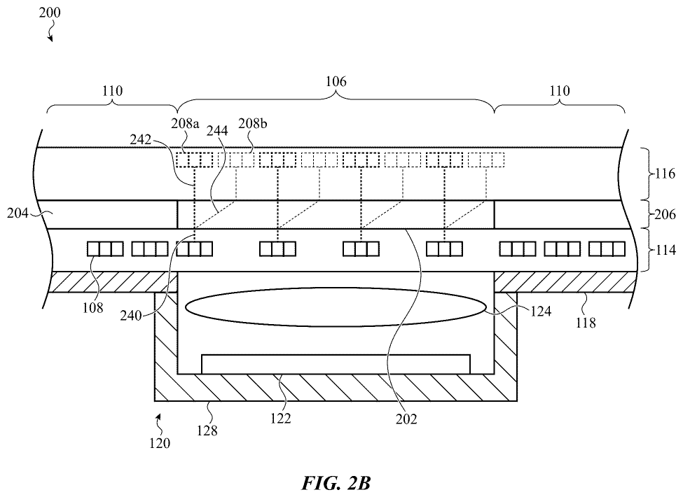

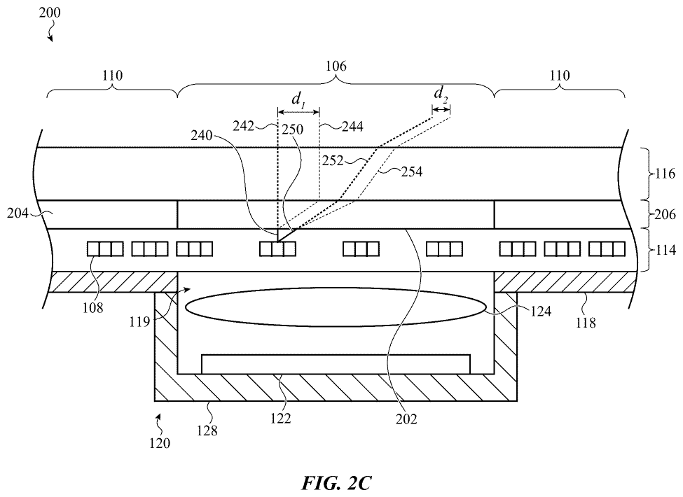

The electronic devices described herein may include a birefringent layer positioned between a cover layer and a display of the electronic device. For example, FIGS. 2A-2C show partial cross-sectional side views of a variation of an electronic device 200. The electronic device 200 may be configured in any manner (and using the same figure labels for like components) as described with respect to the electronic device 100 of FIGS. 1A-1C, except that the electronic device 200 includes a birefringent layer 202 positioned between the display stack 114 and the cover layer 116. The birefringent layer 202 is configured to split a ray of light that is incident on the birefringent layer 202 into two or more rays (referred to herein as “split rays”) based on polarization. The birefringent layer 202 may be formed from any suitable birefringent material, which may include a uniaxial birefringent material or a biaxial birefringent material. For the purpose of discussion, the birefringent layers discussed herein will be discussed in the context of uniaxial birefringent materials, such as calcite, quartz, a polymerized liquid crystal, or the like.

An incident ray of light will, as long as it is not aligned with an optical axis of the birefringent layer 202, be split into two split rays, including a first split ray (referred to herein as the “ordinary ray”) and a second split ray (referred to herein as the “extraordinary ray”) having different polarizations. The ordinary ray and the extraordinary ray will exit the birefringent layer 202 with a lateral displacement between the split rays that depends at least in part on i) the angle of incidence of the received ray on the birefringent layer 202, ii) properties of the birefringent layer 202 such as direction of an optical axis of the birefringent layer 202, the thickness of the birefringent layer 202, and the birefringence of the material forming the birefringent layer 202. Accordingly, in some variations the birefringent layer 202 may be designed to reduce the visibility of the light-transmitting regions 112 of the imaging region 106 of a display 104.

For example, the birefringent layer 202 may be configured to replicate the appearance of various display pixels 108 within the imaging region 106 of the display 104, such as illustrated in FIG. 2B. Specifically, each display pixel 108 within the imaging region 106 is depicted in FIG. 2B as emitting a corresponding ray 240 represented by a solid line (only one of these rays is labeled in FIG. 2B for simplicity of illustration). As the ray 240 enters the birefringent layer 202, it will be split into an ordinary ray 242 and an extraordinary ray 244. The ordinary ray 242 and extraordinary ray 244 associated with each emitted ray 240 will have a lateral displacement as it exits the birefringent layer 202. This lateral displacement (also referred to as the “ray displacement” of the birefringent layer) may be selected, based on the design of the birefringent layer 202, to replicate the appearance of the display pixels 108 within the imaging region 106.

For example, when a display pixel 108 in the imaging region 106 is operated to generate light, the display pixel 108 will, for a given viewing angle (i.e., the angle at which an observer views the cover layer 116 and the display 104), project i) a first image of the display pixel at a first location of the cover layer using ordinary rays generated as light generated by the display pixel 108 passes through the birefringent layer 202, and ii) a second image of the display pixel at a second location of the cover layer using extraordinary rays generated as light generated by the display pixel 108 passes through the birefringent layer 202. FIG. 2B illustrates this concept from the perspective of a viewing angle this is normal to the plane of the cover layer 116 and the display 104. Specifically, each display pixel 108 may generate rays (e.g., emitted rays 240) that enter the birefringent layer 202 with normal incidence. The ordinary rays generated as the emitted rays enter the birefringent layer 202 may collectively project a first image 208a (also referred to herein as the “ordinary image”) of the display pixel 108, and the extraordinary rays generated as the emitted rays enter the birefringent layer 202 may collectively project a second image 208b (also referred to herein as the “extraordinary image”) of the display pixel 108. The birefringent layer 202 may be configured to provide enough lateral displacement between the ordinary and extraordinary rays such that the corresponding first image 208a and the second image 208b of a given display pixel do not overlap.

Accordingly, when viewed from a normal incidence, each display pixel 108 will appear as two different display pixels (e.g., the first image 208a and the second image 208b projected by that display pixel 108). This in turn may cause the imaging region 106 of the display to appear as if it has a higher pixel density, and may reduce the visible differences between the imaging region 106 and the peripheral region 110. As a result, it may be less likely that a user will specifically notice the imaging region 106 of the display 104 when interacting with the electronic device 100.

While it may be desirable to change the apparent pixel density within the imaging region 106, in some instances it may be preferable to not apply this effect to other regions of the display 104. For example, because the peripheral region 110 shown in FIG. 2B has a higher pixel density than the imaging region 106, placing the birefringent layer 202 over the display pixels 108 of the peripheral region may cause overlap between the projected images of adjacent display pixels (e.g., a projected image formed from extraordinary rays of a first display pixel may at least partially overlap a projected image formed from ordinary rays of a second display pixel). In other words, the light exiting variation spatial locations of the display 104 within the peripheral region may include light from two different pixels, which may complicate the operation of the display 104 when projecting visual content.

Accordingly, in some variations the birefringent layer 202 may be sized such that it only covers a portion of the display stack 114. In these variations, the birefringent layer 202 may be locally positioned within the imaging region 106, so that it only overlaps display pixels 108 of the imaging region 106. In these variations (such as shown in FIGS. 2A-2C), the birefringent layer 202 is sized and shaped to correspond to the size and shape of the imaging region 106 of the display 104. Accordingly, the birefringent layer 202 may be positioned between the cover layer 116 and the display stack 114 within the imaging region 106, and may not be positioned between the cover layer 116 and the display stack 114 outside of the imaging region 106 (e.g., within the peripheral region 110).

In some of these variations, the electronic device 100 may include an additional optical material 204 that is coplanar with the birefringent layer 202 and positioned between the cover layer 116 and the display stack 114. In this way, the birefringent layer 202 and the additional optical material 204 may form a common layer 206 having a common thickness between the cover layer 116 and the display stack 114. The additional optical material 204 may have different optical properties than the birefringent layer 202. For example, the additional optical material 204 may be formed from a transparent non-birefringent material, such that portions of the common layer 206 formed by the additional optical material 204 do not exhibit birefringence as light passes through the common layer 206. Accordingly, in these variations the common layer 206 may be positioned between the cover layer 116 and the display stack 114 such that the birefringent layer 202 is positioned between the cover layer 116 and the display stack 114 within the imaging region 106 of the display 104 (e.g., to increase the apparent pixel density of the imaging region 106) and the additional optical material 204 is positioned between the cover layer 116 and the display stack 114 within the peripheral region 110 (e.g., to maintain the apparent pixel density of the peripheral region 110). In some variations, the additional optical material 204 is an optically clear adhesive, which may also be used to connect the cover layer 116 to the display stack 114. In other variations, the additional optical material 204 is glass, crystal (e.g., sapphire), or a transparent polymer (e.g., plastic). In some variations the additional optical material 204 and the cover layer 116 may be formed from a common material.

In some variations in which the birefringent layer 202 is sized to cover only a portion of the display stack 114, the birefringent layer 202 lay may be at least partially embedded within the cover layer 116, such that a portion of the birefringent layer 202 is coplanar with a corresponding portion of the cover layer 116. Additionally or alternatively, the birefringent layer 202 may be at least partially embedded within the display stack 114, such that a portion of the birefringent layer 202 is coplanar with a corresponding portion of the display stack 114 (e.g., coplanar with one or more layers of the display stack 114).

While the birefringent layer 202 may increase the apparent pixel density of at least the imaging region 106 of the display 104, this effect may depend on the viewing angle at which the display 104 is observed. For example, birefringent layer 202 may be configured such that, when viewed from a normal incidence, the projected images of the display pixels 108 in the imaging region 106 may have regular spacing (e.g., the spacing between the projected ordinary and extraordinary images of a first display pixel may be the same as the spacing between the projected extraordinary image of the first display pixel and the projected ordinary image of an adjacent second display pixel). If the display 104 is viewed from a different angle, the spacing between the ordinary and extraordinary images projected by a display pixel may decrease, and in some instances the ordinary and extraordinary images projected by a display pixel may even overlap. Accordingly, at certain viewing angles, a user may still be able to perceive the reduced pixel density of the imaging region 106.

FIG. 2C illustrates an example of this effect in an example where the optical axis of the birefringent layer 202 is selected such that the extraordinary and ordinary rays have the largest display for received rays having normal incidence on the birefringent layer 202. Accordingly, an outgoing ray 240 that is generated by a display pixel 108 and has normal incidence on the birefringent layer 202 will be split into ordinary and extraordinary rays 242, 244 that exit the birefringent layer 202 (and eventually the cover layer 116) with a first separation distance d₁. In the same display pixel 108 emits another ray 250 that is incident on the birefringent layer 202 with a non-normal angle of incidence, this ray 250 will be split into corresponding ordinary and extraordinary rays 252, 254 that exit the birefringent layer 202 (and eventually the cover layer 116) with a second separation distance d₂ less than the first separation distance d₁. Accordingly, when the display is viewed along a viewing angle that corresponds to ray 250, the projected ordinary and extraordinary images of the display pixels 108 will be closer together (e.g., have a smaller separation distance or partially overlap). While the birefringent layer 202 may be configured to prioritize a particular viewing angle, the performance of the birefringent layer 202 will vary as a function of viewing angle.

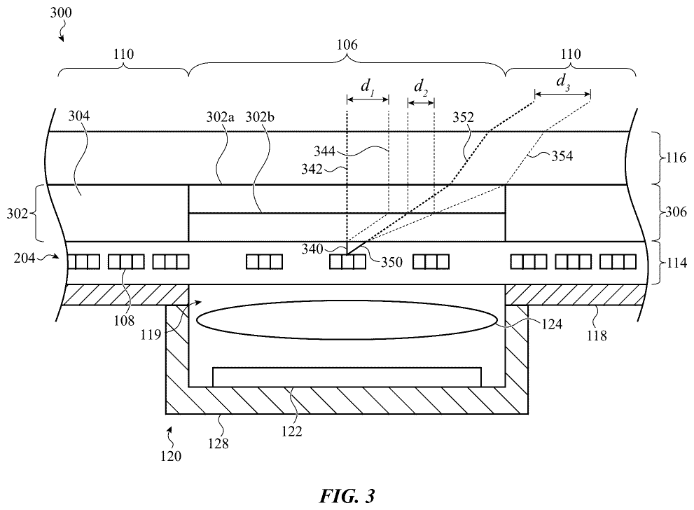

In some variations, an electronic device as described herein may include a birefringent layer stack having multiple stacked birefringent layers. In these instances, the birefringent layer stack may be configured to reduce the impact of viewing angle in increasing the apparent pixel density of a display (or a portion thereof). For example, FIG. 3 shows a partial cross-sectional side view of a variation of an electronic device 300 as described herein. The electronic device 300 may be configured in any manner (and using the same figure labels for like components) as described with respect to the electronic device 200 of FIGS. 2A-2C, except that the electronic device 300 includes a birefringent layer stack 302 positioned between the display stack 114 and the cover layer 116. Specifically, the birefringent layer stack 302 comprises a plurality of stacked birefringent layers 302a-302b. In the variation shown in FIG. 3, the plurality of stacked birefringent layers 302a-302b includes a first birefringent layer 302a and a second birefringent layer 302b positions above the first birefringent layer 302a. In other words, the first birefringent layer 302a is positioned between the second birefringent layer 302b and the display stack 114, whereas the second birefringent layer 302b is positioned between the first birefringent layer 302a and the cover layer 116.

Each birefringent layer of the plurality of stacked birefringent layers 302a-302b has a corresponding optical axis, and the birefringent layer stack 302 may be configured such that different birefringent layers within the birefringent layer stack 302 have different optical axes. For example, the first birefringent layer 302a may have a first optical axis and the second birefringent layer 302b may have a second optical axis with a different orientation than the first optical axis, such that each of these birefringent layers is configured to provide different ray displacements for a given ray of light received by the birefringent layer stack 302.

Accordingly, the first birefringent layer 302a may be configured to provide a first angle-dependent ray displacement for light entering the first birefringent layer 302a, and the second birefringent layer 302b may be configured to provide a different second angle-dependent ray displacement for light entering the second birefringent layer 302b. Specifically, a ray of light incident on the first birefringent layer 302a with particular angle of incidence will experience a first ray displacement according to the first angle-dependent ray displacement. Conversely, a ray of light incident on the second birefringent layer 302b with the same angle of incidence will experience a second ray displacement (e.g., according to the second angle-dependent ray displacement) with a different magnitude. Overall, the birefringent layer stack 302 is configured to split received rays of light into corresponding ordinary and extraordinary rays having an overall angle-dependent ray displacement that depends on the corresponding angle-dependent ray displacements provided by the individual stacked birefringent layers 302a-302b. The overall ray displacement provided by birefringent layer stack 302 may be less sensitive to changes in the angle of incidence as compared to a single birefringent layer (e.g., the birefringent layer 202 of FIGS. 2A-2C), which may improve performance across a range of viewing angles.

For example, the first birefringent layer 302a and the second birefringent layer 302b may be configured to provide corresponding angle-dependent ray displacements in a common direction, such as shown in FIG. 3. Specifically a first ray 340 and a second ray 350 may be emitted by a display pixel 108 and be incident on the first birefringent layer 302a at two different angles of incidence. For the purpose of illustration, these rays 340, 350 are illustrated as entering with the same respective angles of incidence as the rays 240, 250 shown in FIG. 2C (e.g., the first ray 340 enters the first birefringent layer 302a with a normal angle of incidence and the second ray 350 enters the first birefringent layer 302a with a non-normal angle of incidence. Each of these rays will be split into corresponding ordinary and extraordinary rays (e.g., the first ray 340 is split into ordinary ray 342 and extraordinary ray 344 and the second ray 350 is split into ordinary ray 352 and extraordinary ray 354) that will exit the first birefringent layer 302a at a corresponding lateral separation according to the first angle-dependent ray displacement. For example, the first birefringent layer 302a may be configured to provide the same angle-dependent ray displacement as the birefringent layer 202 of FIGS. 2A-2C, such that the ordinary and extraordinary rays 352, 354 corresponding to the first ray 340 exit the first birefringent layer 302a with a first separation distance d₁ and the ordinary and extraordinary rays 352, 354 corresponding to the second ray 350 exit the first birefringent layer 302a with a second separation distance d₂.

The second birefringent layer 302b is positioned to receive light after it exits the first birefringent layer 302a. If a given ray has already been split into corresponding ordinary ray and extraordinary ray by the first birefringent layer 302a, the second birefringent layer 302b may not split these ordinary and extraordinary rays (as these rays are already polarized). The second birefringent layer 302b may, however, be configured to further increase the lateral displacement between the ordinary and extraordinary rays according to the second angle-dependent ray displacement. In other words, the ordinary and extraordinary rays corresponding to a given input ray (e.g., received and split by the first birefringent layer 302a) may enter and exit the second birefringent layer 302b with different lateral separations depending on the angle of incidence of the ordinary and extraordinary rays on the second birefringent layer 302b.

For example, in the variation shown in FIG. 3, the second optical axis is selected such that rays entering the second birefringent layer 302b with a normal incidence are aligned with the second optical axis. Accordingly, the ordinary and extraordinary rays 342, 344 corresponding to the first ray 340 may enter the second birefringent layer 302b at normal incidence, and thus maintain the first separation distance d₁ as the ordinary and extraordinary rays 342, 344 exit the second birefringent layer 302b (and eventually the cover layer 116). Conversely, the ordinary and extraordinary rays 352, 354 corresponding to second ray 350 may enter the second birefringent layer 302b at non-normal incidence, and the second birefringent layer 302b may act to increase the lateral displacement between the ordinary and extraordinary rays 352, 354. Specifically, the ordinary and extraordinary rays 352, 354 may exit the second birefringent layer 302b (and eventually the cover layer 116) with a third separation distance d₃ that is larger than the second separation distance d₂. Accordingly, the birefringent layer stack 302 may provide a larger beam displacement for rays with non-normal angles of incidence as compared to the single birefringent layer 202 of FIGS. 2A-2C. This in turn may provide for improved performance across a range of viewing angles.

While the birefringent layer stack 302 is shown in FIG. 3 as having two stacked birefringent layers, it should be appreciated that in other variations the birefringent layer stack 302 may include one or more additional birefringent layers (e.g., the birefringent layer stack 302 may include three or more stacked birefringent layers). These additional birefringent layers may have different optical axes, and thereby provide a different corresponding angle-dependent ray displacement. Accordingly, the plurality of stacked birefringent layers 302a-302b may provide any combination of corresponding angle-dependent ray displacement as needed to provide a desired overall angle-dependent ray displacement of the birefringent layer stack 302. The plurality of stacked birefringent layers 302a-302b may be made using any combination of materials (e.g., the first birefringent layer 302a and the second birefringent layer 302b may be formed from the same material or may be formed from different materials), relative thicknesses (e.g., the first birefringent layer 302a and the second birefringent layer 302b may have a common thickness or may have different thicknesses) and/or relative footprints (e.g., the first birefringent layer 302a and the second birefringent layer 302b may have a common size or may have different sizes) as may be desired. It should also be appreciated that different birefringent layers within the birefringent layer stack may be separated by one or more non-birefringent layers. For example, the first birefringent layer 302a may be separated from the second birefringent layer 302b by an optically clear adhesive that connects the first birefringent layer 302a to the second birefringent layer 302b. In other variations, the first birefringent layer 302a and the second birefringent layer 302b may be separated by a transparent spacer layer (or an air gap) if so desired.

As discussed herein with respect to the birefringent layer 202 of FIGS. 2A-2C, in some instances it may be desirable for the birefringent layer stack 302 to be sized such that it only covers a portion of the display stack 114. In these variations, the birefringent layer stack 302 may be locally positioned within the imaging region 106, so that it only overlaps display pixels 108 of the imaging region 106. In some instances, the birefringent layer stack 302 may be coplanar with an additional optical material 304, such that the birefringent layer stack 302 forms a corresponding portion of a common layer 306 (such as described herein with respect to the additional optical material 204 and the common layer 206 of FIGS. 2A-2C).

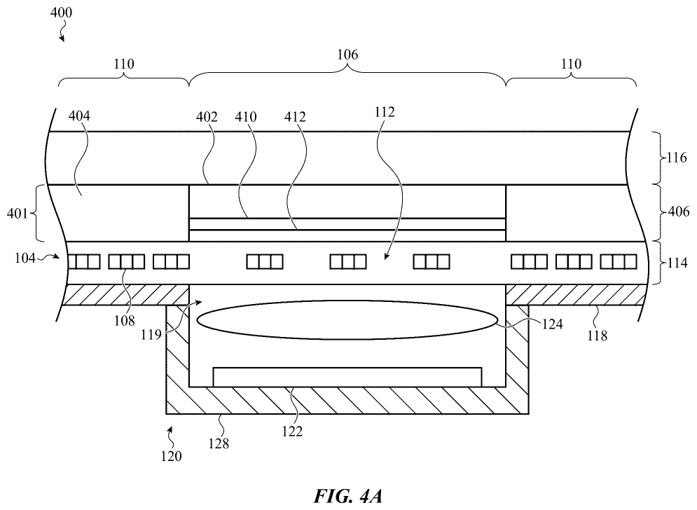

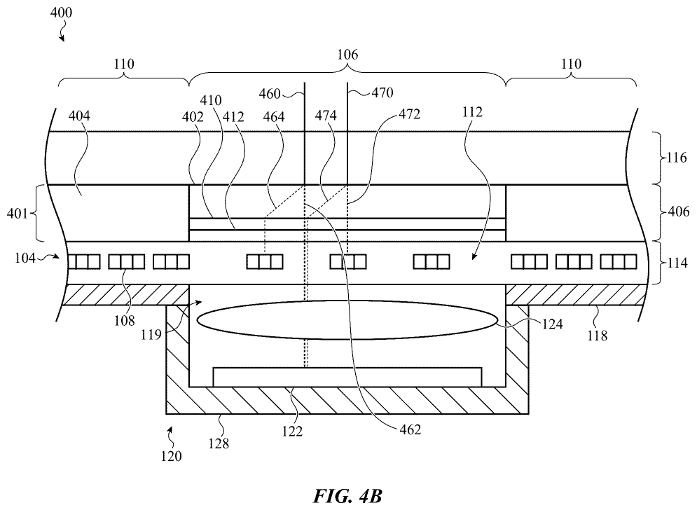

In some instance, a set of birefringent layers (e.g., a single birefringent layer or a birefringent layer stack) may be used to help improve the image quality of images captured by a behind-display imaging device. For example, FIGS. 4A and 4B show partial cross-sectional side views of a variation of an electronic device 400 as described herein. The electronic device 400 may be configured in any manner (and using the same figure labels for like components) as described with respect to the electronic device 200 of FIGS. 2A-2C, except that the electronic device 400 includes a layer stack 401 positioned between the display stack 114 and the cover layer 116 of the electronic device. The layer stack 401 is also positioned the imaging device 120 and the cover layer 116, such that light measured by the imaging device 120 passes through the layer stack 401.

The layer stack 401 includes a set of birefringent layers 402, a retarder layer 410, and a polarizing layer 412. The set of birefringent layers 402 may include a single birefringent layer (such as described herein with respect to the birefringent layer 202 of FIGS. 2A-2C) or a plurality of birefringent layers (such as described herein with respect to the birefringent layer stack 302 of FIG. 3). When the display 104 is operated to generate light, the set of birefringent layers 402 may split rays of outgoing light emitted by the display pixels 108 into ordinary and extraordinary rays as discussed in more detail herein. This may increase the apparent pixel density of the display 104 (or a portion thereof), such as described in more detail herein. Similarly, the set of birefringent layers 402 may receive rays of light that enter the electronic device 400 through the cover layer 116, and may similarly split these incoming rays into corresponding ordinary and extraordinary rays.

For example, FIG. 4B shows a pair of rays (a first incoming ray 460 and a second incoming ray 470) that is received by the electronic device 400 through the cover layer 116. The first incoming ray 460 and the second incoming ray 470 are incident on different locations of the set of birefringent layers 402, but with a common angle of incidence (e.g., normal incidence). Accordingly, the set of birefringent layers 402 splits the first incoming ray 460 into a corresponding ordinary ray 462 and a corresponding extraordinary ray 464, and splits the second incoming ray 470 into a corresponding ordinary ray 472 and a corresponding extraordinary ray 474. As shown there, the first incoming ray 460 is positioned such that its ordinary ray 462 passes through a light-transmitting region 112 of the display 104 within the imaging region 106, such that the ordinary ray 462 may be received and measured by the imaging device 120. The extraordinary ray 464 corresponding to the first incoming ray 460 may (as depicted in FIG. 4B) be absorbed or reflected by an opaque portion of the display stack 414, or may pass through display at a different location.

The second incoming ray 470 is positioned such that its extraordinary ray 474 exits the set of birefringent layers 402 along a common path as the ordinary ray 462 generated from the first incoming ray 460. In this way, the ordinary ray 462 and extraordinary ray 474 may follow a common path as they travel through the display 104. Accordingly, rays of light measured by the imaging device 120 may include a superposition of light received at different spatial locations of the set of birefringent layers 402 (e.g., an ordinary ray generated from a first location superimposed with an extraordinary ray generated from a second location). Overall, the imaging device 120 captures two superimposed views of a scene through the display 104, where one view is formed from the ordinary rays generated by the set of birefringent layers 402 and the other view is formed from the extraordinary rays generated by the set of birefringent layers 402.

If the light exiting the set of birefringent layers 402 is not further modified, these views of the scene will add incoherently. In these instances, an image captured by the imaging device 120 may not significantly differ from an image captured by the imaging device 120 when the electronic device 400 does not include the set of birefringent layers 402 (such as the electronic device of FIGS. 1A-1C). In variations in which a retarder layer 410 and a polarizing layer 412 are positioned between the set of birefringent layers 402 and the display stack 114, the retarder layer 410 and a polarizing layer 412 alter light exiting the set of birefringent layers 402 layers such that the two views of the scene will add coherently (e.g., constructively interfere).

Specifically, the retarder layer 410 may be positioned to receive light after it exits the set of birefringent layers 402 (e.g., the retarder layer 410 may be positioned between the set of birefringent layers 402 and the polarizing layer 412), and may be configured to reduce a phase difference between ordinary and extraordinary rays received by the retarder layer 410. Because the ordinary and extraordinary rays for a given ray of incoming light take different paths through the set of birefringent layers 402, these rays may exit the set of birefringent layers 402 with an angle-dependent phase difference (e.g., that depends on the angle of incidence on the set of birefringent layers 402).

Accordingly, by providing a polarization-dependent phase delay to light passing through the retarder layer 410, the retarder layer 410 may reduce the angle-dependent phase difference between the ordinary and extraordinary rays it receives from the set of birefringent layers 402. For example, the retarder layer 410 may be configured to prioritize a particular angle of incidence (e.g., normal incidence), such that ordinary and extraordinary rays received by the retarder layer 410 from the set of birefringent layers 402 at this angle of incidence will be in phase as it exits the retarder layer 410.

The polarizing layer 412 may be configured to receive the ordinary and extraordinary rays after they have passed through the retarder layer 410, and may be configured to convert the ordinary and extraordinary rays into a common polarization state. In some variations, the polarizing layer 412 is a 45-degree polarizer (e.g., a polarizer with a polarization direction that is angled at 45 degrees relative to the corresponding polarization directions of each of the ordinary and extraordinary rays). In other variations, polarizing layer 412 is a depolarizer.

Accordingly, the retarder layer 410 and the polarizing layer 412 collectively convert ordinary and extraordinary rays into a light having a common phase and polarization state. In this way, the two views of a scene measured by the imaging device 120 may constructively interfere. This may suppress one or more diffraction orders as light passes through the display stack 114, which may reduce the presence of artifacts in images captured by the imaging device 120.

As discussed herein with respect to the birefringent layer 202 of FIGS. 2A-2C, in some instances it may be desirable for the layer stack 401 to be sized such that it only covers a portion of the display stack 114. In these variations, the layer stack 401 may be locally positioned within the imaging region 106, so that it only overlaps display pixels 108 of the imaging region 106. In some instances, the layer stack 401 may be coplanar with an additional optical material 404, such that the layer stack 401 forms a corresponding portion of a common layer 406 (such as described herein with respect to the additional optical material 204 and the common layer 206 of FIGS. 2A-2C).

In the variation shown in FIGS. 4A and 4B, the retarder layer 410 is configured as a single continuous layer, where the entire retarder layer 410 provides a polarization-dependent phase delay as described herein. In these instances, light will experience a polarization-dependent phase delay regardless of where light enters the retarder layer 410 from the set of birefringent layers 402. In other variations, the retarder layer 410 may be configured as an arrayed layer in which only certain regions of the retarder layer 410 provides a polarization-dependent phase delay. For example, in some variations the retarder layer 410 is configured as a layer that includes an array of coplanar retarder regions. Each retarder region may act to provide a polarization-dependent phase delay as described herein. The various retarder regions may be separated by one or more materials that do not provide a polarization-dependent phase delay.

In these variations, as ordinary and extraordinary rays exit the set of birefringent layers 402, only certain ordinary and extraordinary rays will interact with retarder regions (and thereby experience a polarization-dependent phase change), whereas the remaining ordinary and extraordinary rays will not experience a polarization-dependent phase change. In some of these variations, an array of coplanar retarder regions may be configured such each retarder region is positioned over a corresponding light-transmitting regions 112 of the display 104. In this way, the retarder regions may be locally positioned to receive and alter light that is measured by the imaging device 120. The retarder regions may not be positioned over the display pixels 108, such that the retarder layer 410 does not alter light that is emitted by the display pixels 108 of the display 104.

Similarly, the polarizing layer 412 is shown in FIGS. 4A and 4B as configured as a single continuous layer, where the entire polarizing layer 412 provides a polarizing function as described herein. In these instances, ordinary and extraordinary rays will experience a polarization change regardless of where these rays enter the polarization layer 412. Alternatively, the polarizing layer 412 may be configured as an arrayed layer in which only certain regions of the polarizing layer 412 change the polarization of ordinary and extraordinary rays. For example, in some variations the polarizing layer 412 is configured as a layer that includes an array of coplanar polarizing regions. Each polarization region may act to convert ordinary and extraordinary rays received from the retarder layer 410 to a common polarization state. The various polarization regions may be separated one or more regions that are formed from material(s) that do not alter the polarization state of ordinary and extraordinary rays.

In these variations, as ordinary and extraordinary rays exit the retarder layer 410, only certain ordinary and extraordinary rays will interact with polarizing regions (and thereby experience a change in polarization), whereas the remaining ordinary and extraordinary rays will maintain their polarization as they pass through the polarization layer 412. In some of these variations, an array of coplanar polarizing regions may be configured such each polarizing region is positioned over a corresponding light-transmitting regions 112 of the display 104. In this way, the polarizing regions may be locally positioned to receive and alter light that is measured by the imaging device 120. The polarizing regions may not be positioned over the display pixels 108, such that the polarizing layer 412 does not alter light that is emitted by the display pixels 108 of the display 104.

Although the disclosure above is described in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the some embodiments of the invention, whether or not such embodiments are described and whether or not such features are presented as being a part of a described embodiment. Thus, the breadth and scope of the present invention should not be limited by any of the above-described exemplary embodiments but is instead defined by the claims herein presented.

What is claimed is:

1. An electronic device comprising:
a cover layer;
a display;
an imaging device positioned to collect light through an imaging region of the display; and
a layer stack positioned between the imaging device and the cover layer, wherein the layer stack comprises:
a set of birefringent layers;
a retarder layer; and
a polarizing layer.

2. The electronic device of claim 1, wherein:
the set of birefringent layers is configured to split incoming rays of light into ordinary rays and extraordinary rays;
the retarder layer is configured to reduce a phase difference between the ordinary rays and the extraordinary rays; and
the polarizing layer is configured to convert the ordinary rays and the extraordinary rays into a common polarization state.

3. The electronic device of claim 2, wherein the polarizing layer is a 45-degree polarizer.

4. The electronic device of claim 2, wherein the polarizing layer is a depolarizer.

5. The electronic device of claim 1, wherein:
the set of birefringent layers comprises a plurality of birefringent layers.

6. The electronic device of claim 1, wherein:
the retarder layer is configured as a continuous layer.

7. The electronic device of claim 1, wherein:
the polarizing layer is configured as a continuous layer.

8. An electronic device comprising:
a cover layer;
a display; and
a plurality of stacked birefringent layers positioned between the display and the cover layer, wherein:
the plurality of stacked birefringent layers is configured to split incoming rays of light into ordinary rays and extraordinary rays having an overall angle-dependent ray displacement;
the plurality of stacked birefringent layer comprises:
a first birefringent layer having a first optical axis; and
a second birefringent layer having a second optical axis with a different orientation that the first optical axis.

9. The electronic device of claim 8, wherein:
the first birefringent layer is configured to provide a first angle-dependent ray displacement in a first direction; and
the second birefringent layer is configured to provide a second angle-dependent ray displacement in the first direction.

10. The electronic device of claim 8, comprising an imaging device, wherein:
the plurality of stacked birefringent layers is positioned between the imaging device and the cover layer.

11. The electronic device of claim 10, wherein:
the imaging device is positioned to collect light through an imaging region of the display;
the display comprises a peripheral region at least partially surrounding the imaging region; and
the display has a higher pixel density in the peripheral region than in the imaging region.

12. The electronic device of claim 11, wherein:
the plurality of stacked birefringent layers is positioned between the display and the cover layer within the imaging region; and
the plurality of stacked birefringent layers is not positioned between the display and the cover layer within the peripheral region.

13. The electronic device of claim 12, comprising an additional optical material positioned between the display and the cover layer within the peripheral region, wherein the additional optical material is coplanar with the plurality of stacked birefringent layers.

14. An electronic device comprising:
a cover layer;
a display comprising an imaging region and a peripheral region at least partially surrounding the imaging region;
an imaging device positioned to collect light through an imaging region; and
a set of birefringent layers, wherein:
the set of birefringent layers is positioned between the display and the cover layer within the imaging region; and
the set of birefringent layers is not positioned between the display and the cover layer within the peripheral region.

15. The electronic device of claim 14, wherein:
the display has a higher pixel density in the peripheral region than in the imaging region.

16. The electronic device of claim 14, comprising an additional optical material positioned between the display and the cover layer within the peripheral region, wherein the additional optical material is coplanar with the set of birefringent layers.

17. The electronic device of claim 16, wherein the additional optical material is an optically clear adhesive.

18. The electronic device of claim 16, wherein the additional optical material and the cover layer are formed from a common material.

19. The electronic device of claim 14, wherein the display comprises:
a display stack; and
an opaque backing layer positioned behind the display stack.

20. The electronic device of claim 19, wherein the opaque backing layer defines an aperture that is positioned over the imaging device.
